(19) United States
(12) Patent Application Publication
(10) Pub. No.: US 2026/0120760 A1
(43) Pub. Date: Apr. 30, 2026

(54) METHOD FOR MODIFYING A CONDUCTANCE VALUE OF A PHASE CHANGE MEMORY CELL DURING AN INFERENCE CYCLE

(71) Applicant: COMMISSARIAT À L'ENERGIE ATOMIQUE ET AUX ENERGIES ALTERNATIVES, Paris (FR)

(72) Inventors: Joel MINGUET LOPEZ, Grenoble (FR); Tifenn Hirtzlin, Grenoble (FR); Gabriele Navarro, Grenoble (FR)

(73) Assignee: COMMISSARIAT À L'ENERGIE ATOMIQUE ET AUX ENERGIES ALTERNATIVES, Paris (FR)

(21) Appl. No.: 19/368,780

(22) Filed: Oct. 24, 2025

(30) Foreign Application Priority Data
Oct. 24, 2024 (FR) 24/11636

(51) Int. Cl. G11C 11/54; G11C 13/00

(52) U.S. Cl. CPC G11C 11/54; G11C 13/0004; G11C 13/004; G11C 13/0069; G11C 2013/0076

(57) ABSTRACT

A method for modifying a conductance or resistance value within a resistance distribution range defined around a median resistance distribution value of at least one phase change memory cell, the method including: a determination step in which a melting current and an amorphous phase current are determined; a quenching step in which a first pulse with a steep falling ramp having a quenching effect is applied to the at least one phase change memory cell; a crystallization step in which a second pulse with a progressively falling ramp is applied to at least one phase change memory cell.

### TECHNICAL FIELD

The invention concerns the field of neural networks and more specifically a method for modifying a conductance value of a phase change memory cell.

### PRIOR ART

The artificial neural networks are widely used in many fields of artificial intelligence, such as image recognition, speech recognition, etc.

Bayesian-type neural networks are particularly interesting in that they allow quantification of the uncertainty of their predictions. For this purpose, the synaptic weights, that is to say a parameter of the neural network quantifying the strength of a connection between two neurons, are not represented by a single value but by a distribution of conductance or resistance values. This distribution is characterized by a median value of the conductance or resistance distribution, and a standard deviation, which are determined during a learning process.

The inference phase refers to the phase during which the neural network is used to make predictions. The inference phase takes place after a learning phase.

It is known to implement the distribution of conductance values characterizing a synaptic weight of a Bayesian-type neural network by means of a plurality of resistive memory cells. This solution, requiring the use of a large number of resistive memory cells, results in particular in significant power consumption of the neural network during the inference phase. Furthermore, this solution uses a large silicon area, thereby reducing the density of the neural network and increasing manufacturing costs. A solution consists in implementing the distribution of conductance values by means of a single memory cell, such as an emergent resistive memory cell such as a filamentary memory, also known as RRAM (resistive random-access memory). Indeed, an electrical reprogramming pulse applied to the filamentary memory RRAM allows its conductance value to be randomly modified around the median conductance value during each inference cycle. It is thus possible to represent a distribution of conductance values during inference cycles using a single cell.

However, the application of the reprogramming pulse degrades the filamentary memory RRAM and can only be performed a limited number of times before a likely failure of the filamentary memory RRAM occurs. This greatly restricts the use of this solution.

It is also possible to apply a reading electrical pulse to the filamentary memory RRAM in order to modify its conductance value. Indeed, the read pulse is less aggressive than the reprogramming pulse, allowing for a longer lifespan, and disrupts the conductance value of the filamentary memory RRAM.

The disadvantage is that the distribution range, that is to say, the standard deviation, of conductance obtained with a reading pulse is very small and unsuitable for an industrially scalable product. Furthermore, the filamentary memories RRAM exhibit high conductance values, which significantly increases their power consumption, in particular during combined multiplier-accumulator operations, also known as MAC («multiply-accumulate») operation.

Therefore, there is a need for a single memory cell making it possible to represent a synaptic weight of a Bayesian network that overcomes the above drawbacks.

### DISCLOSURE OF THE INVENTION

One embodiment concerns a method for modifying a conductance, or respectively resistance value, in a resistance distribution range defined around a median value of resistance distribution, or respectively conductance distribution, of at least one phase change memory cell, said at least one phase change memory cell being comprised in a memory array comprising a plurality of memory cells, the at least one memory cell comprising a lower electrode, an upper electrode, and a phase change material located between the lower electrode and the upper electrode, the phase change material being capable of assuming a crystalline, partially amorphous, or completely amorphous state at an interface with the lower electrode, the method being implemented by a neural network and comprising:
A determination step in which a melting current and an amorphous phase current are determined for the at least one phase change memory cell, the melting current corresponding to the current causing at least one partial localized melting of the phase change material at the interface with the lower electrode when it is applied to the at least one phase change memory cell, the amorphous phase current corresponding to the current causing a creation of a completely amorphous state at the interface with the lower electrode when it is applied to the at least one phase change memory cell;
A quenching step in which a first pulse at a modification current greater than or equal to the melting current, and strictly less than the amorphous phase current, is applied to the at least one phase change memory cell, the first pulse having a rising ramp then a steep falling ramp having a quenching effect;
A crystallization step in which a second pulse with the modification current is applied to the at least one phase change memory cell, said at least one phase change memory cell being identical to the at least one phase change memory cell of the quenching step, the second pulse having a rising ramp followed by a progressive falling ramp.

The conductance value of the phase change memory cell is directly related to a resistance value since the conductance is equal to the inverse of the resistance of the phase change memory cell. The method according to the invention therefore corresponds to a method for modifying the conductance value, or equivalently, the resistance of the phase change memory cell.

A neural network comprises a plurality of phase change memory cells grouped in a memory array.

A phase change memory cell, called PCM is a type of non-volatile memory that relies on a reversible phase change of a material to store information. More specifically, an electrical resistivity of the phase change material, or in other words, the value of its conductance, varies as a function of the ratio of a highly resistive amorphous phase and a ratio of a low-resistive crystalline phase of said phase change material. The phase change material is located between a lower electrode and an upper electrode. The phase change material can assume:
a crystalline state in which the phase change material in contact with the lower electrode is completely in the crystalline phase,
a partially amorphous state in which the phase change material in contact with the lower electrode is partially in the crystalline phase and partially in the amorphous phase,
a completely amorphous state in which the phase change material in contact with the lower electrode is completely in the amorphous phase.

To determine the state of the phase change material at the interface with the lower electrode of a given phase change memory cell, the resistance of the phase change memory cell is measured as a function of various applied voltages. A threshold voltage detection, that is to say, a voltage at which a sudden decrease in the resistance of the phase change memory cell is detected, indicates a completely amorphous state of the material at the interface with the lower electrode.

The term threshold resistance, respectively threshold conductance, refers to the resistance, respectively the conductance, of the phase change memory cell for which a threshold voltage is detected.

The phase change is achieved by applying an electrical pulse between the lower and upper electrodes, which heats the phase change material of the phase change memory cell by the Joule effect. More precisely, the electrical pulse induces at least partial melting of the phase change material. Then, according to a cooling temperature profile, that is to say, according to the applied falling ramp, the crystalline phase or the amorphous phase is created in the phase change material.

The electrical pulse is defined as having a rising ramp during which the pulse current increases and goes from a minimum value, which may be equal to zero, to a maximum value, corresponding to the nominal current value, subsequently also referred to as the modification current, and a falling ramp during which the pulse current decreases and goes from the nominal current value to the minimum value.

Depending on the temperature profile applied by the electrical pulse, that is to say, after at least partial melting of the phase change material and depending on the applied falling ramp, the phase change material changes state so as to become more crystalline or more amorphous than before the pulse was applied.

More specifically, after melting, rapid cooling of the phase change material, that is to say, a steep falling ramp, leads to the appearance of the amorphous phase, while slow cooling, that is to say, a gradual ramp, leads to the appearance of the crystalline phase at the interface with the lower electrode.

For example, a pulse with a rectangular profile corresponds to a pulse whose rising ramp and falling ramp are substantially instantaneous, such that the current rise and fall are rapid. The pulse with a rectangular profile causes the phase change material to melt and then cool rapidly, which results in a greater presence of the amorphous phase at the interface with the lower electrode than before the pulse. More precisely, the amorphous phase is generated at high temperature, that is to say, during the melting of the phase change material, and then the rapid cooling allows for the preservation of this amorphous phase.

The duration of the applied pulse is a standard pulse duration in a neural network, typically in the range of a hundred nanoseconds. The nominal current value of the pulse is therefore decisive in a temperature and quantity of phase change material that is heated by the pulse, and therefore the quantity of material at the interface with the lower electrode that can change phase.

For a phase change memory cell, a melting current is distinguished, which corresponds to a nominal current value of a pulse for which at least one quantity of the phase change material in contact with the lower electrode can change phase, such that the conductance value of the phase change memory cell varies. A pulse applied to the phase change memory cell with a nominal current lower than the melting current causes no phase change and therefore no conductance change.

An amorphous phase current is also distinguished, which corresponds to the nominal current value of a pulse beyond which the phase change material becomes completely amorphous at the interface with the lower electrode.

The amorphous phase current is determined by successively applying a pulse with a steep falling ramp that has a quenching effect on the phase change memory cell, starting with a crystalline state. These pulses will gradually change the conductance, or resistance, value of the phase change memory cell. When a threshold voltage appears in the phase change memory cell, that is to say, when the phase change memory cell is in a completely amorphous state at the interface with the lower electrode, the current of the last applied pulse is defined as the amorphous phase current.

In other words, from the value of the pulse current causing the appearance of a threshold voltage, and therefore the creation of a completely amorphous state at the interface with the lower electrode, the threshold resistance and the amorphous phase current, which correspond to said pulse current value, are deduced.

During a learning phase, the phase change memory cell is programmed so that the conductance value is equal to a median conductance distribution value. There are several ways of programming the phase change memory cell known to those skilled in the art. Then, during an inference phase, the method seeks to modify the conductance value of the phase change memory cell within a distribution range defined around this median value of the conductance distribution. The distribution range is defined between a lower and an upper conductance value determined during the learning phase around the median value of the conductance distribution.

At each inference cycle, the conductance value of the phase change memory cell is modified within the distribution range so that the median value of the conductance distribution does not vary during the different inference cycles.

Thus, during the inference cycles, the median conductance distribution value can be defined as the median conduction value and the distribution range as the standard deviation.

To perform this modification of the conductance value, the method comprises a determination step. During this step, the melting current and the amorphous phase current are determined for the phase change memory cell. According to one feature of the invention, during the determination step, a threshold voltage and a threshold conductance or a threshold resistance of the at least one phase change memory cell are determined.

Then, the method comprises a quenching step. In this step, a first electrical pulse is applied to the phase change memory cell. The first pulse has a steep falling ramp resulting in the presence of an amorphous phase in the phase change material, for example, a rectangular pulse profile, and a modification current greater than or equal to the melting current and strictly less than the amorphous phase current. Thus, the modification current is selected to be sufficient to locally melt the phase change material while allowing for lower power consumption than that associated with a programming pulse. Furthermore, the use of such a modification current, lower than the amorphous phase current, degrades the phase change memory cell less and therefore allows for a longer lifespan. After the quenching step, the conductance value of the phase change memory cell is therefore reduced.

The method also comprises a crystallization step. In this step, a second electrical pulse is applied to the phase change memory cell. The second pulse has a progressive falling ramp allowing the appearance of a crystalline phase in the phase change material, at the modification current. The falling ramp of the second pulse allows for the local creation of a crystalline phase in the phase change material. After the crystallization step, the conductance value of the phase change memory cell is therefore increased.

The method does not define a sequence between the quenching step and the crystallization step. The quenching step can therefore be followed by the crystallization step or performed after the latter.

Furthermore, the current applied during the first pulse is equal to the current applied during the second pulse. Thus, the reduction in the conductance achieved during the quenching step is substantially equal to the increase in the conductance achieved during the crystallization step, such that the conductance value remains within the distribution range defined around the median value of the conductance distribution.

The quenching and crystallization steps of the method allow maximizing the maintenance of the conductance value of the phase change memory cell within the distribution range defined around the median value of the conductance distribution. Thus, the median value of the conductance distribution is stable during the inference cycles while ensuring satisfactory cycle-to-cycle variability of the conductance value of the phase change memory cell.

The subject matter of the present disclosure may also have one or more of the following features, taken alone or in combination.

In some embodiments, during the determination step, an overall maximum melting current and an overall minimum amorphous phase current are determined.

The overall maximum melting current corresponds to the maximum of the melting currents determined for each phase change memory cell in the memory array. In other words, if a pulse with the overall maximum melting current is applied to all of the phase change memory cells in the memory array, then at least a partial localized melting of the phase change material at the interface with the lower electrode will occur across all of the phase change memory cells in the memory array. Thus, the conductance values of all of the phase change memory cells in the memory array will be modulated.

The overall minimum amorphous phase current corresponds to the minimum of the amorphous phase currents determined for each phase change memory cell in the memory array. In other words, if a pulse with the overall minimum amorphous phase current is applied to all the phase change memory cells in the memory array, then at least one phase change memory cell in the memory array will transition to the fully amorphous state.

To determine the overall minimum amorphous phase current, the conductance, or resistance value, of all the phase change memory cells in the memory array is modified to increasing resistance values, starting with a crystalline state. To do this, pulses with a steeply falling ramp, a quenching effect, and an increasing modification current are applied to all the memory cells. For each resistive state, the occurrence of a threshold voltage across all the phase change memory cells in the memory array is evaluated. As long as no threshold voltage is detected, the injection of a pulse with a steep falling ramp having a quenching effect at a higher modification current continues. The modification current for which a threshold voltage is detected on one or more cells of the memory array is defined as the «overall minimum amorphous phase current».

In some embodiments, during the determination step, an overall maximum melting current and an overall minimum amorphous phase current are determined.

In some embodiments, during the quenching step, the first pulse at the modification current is applied simultaneously to all the phase change memory cells of the memory array, and during the crystallization step, the second pulse is applied simultaneously to all the phase change memory cells of the memory array.

All the phase change memory cells of the memory array are therefore subjected to the same pulse. Thus, the conductance value of all the phase change memory cells is modified simultaneously.

In some embodiments, the modification current is greater than or equal to the overall maximum melting current and strictly less than the overall minimum amorphous phase current.

Thus, the modification current is identical for all phase change memory cells. It is therefore not necessary to know, and therefore store in memory, the melting, amorphous phase, and modification currents for each phase change memory cell.

In some embodiments, the median conductance distribution value, or respectively resistance distribution value, as well as the conductance distribution range, or respectively resistance distribution range, of the at least one phase change memory cell are defined as greater than, respectively less than, a threshold conductance, or respectively threshold resistance, corresponding to a conductance, or respectively resistance, of the at least one phase change memory cell for which a threshold voltage is detected.

Thus, the phase change memory cell remains in a crystalline or partially amorphous state.

In some embodiments, the median conductance distribution value, respectively resistance distribution value, as well as the distribution range of the at least one phase change memory cell are maintained above, respectively below, the threshold conductance, respectively resistance during the quenching and crystallization steps.

In some embodiments, the falling ramp of the first pulse is twice as fast as the falling ramp of the second pulse.

In some embodiments, the steep falling ramp of the first pulse has a duration less than or equal to 30 ns.

In other words, a transition from the modification current to the minimum current is achieved with a duration less than or equal to 30 ns.

In some embodiments, the gradual falling ramp of the second pulse has a duration greater than 30 ns and preferably greater than or equal to 60 ns.

In other words, a transition from the modification current to the minimum current is achieved with a duration greater than 30 ns and preferably greater than or equal to 60 ns.

In some embodiments, the modification current is comprised between the melting current and 1.2 times the melting current.

From experience, 1.2 times the melting current is always less than the amorphous phase current. Thus, the conductance value of the at least one phase change memory cell is achieved around the median value.

In some embodiments, the method comprises a reading step in which a reading pulse at a reading voltage is applied to the at least one phase change memory cell in order to measure the resistance or conductance value.

The method further comprises a reading step that applies a pulse whose voltage is not high enough to modify the conductance of the phase change memory cell. The reading step makes it possible to measure and determine the conductance value of the phase change memory cell. More specifically, the reading step can precisely measure the exact conductance value or determine only whether the conductance value is within the distribution range defined around the median value of the conductance distribution.

The reading step is part of the modification method in that it corresponds to a control of the obtained conductance value. This reading step is not necessarily used as a useful value during the implementation, that is to say, during an inference cycle, of the neural network.

The reading voltage cannot induce a phase change in the memory cell. The reading voltage is therefore lower than the threshold voltage of the phase change memory cell. The reading voltage therefore does not allow a modification of the conductance value of the phase change memory cell. The reading voltage only allows the conductance value to be determined. In other words, the reading voltage allows the conductance value of the phase change memory cell to be measured.

Preferably, the reading voltage is lower than the minimum threshold voltage detected on all the devices present in the memory array.

The reading step is performed after the quenching step and the crystallization step have been completed.

With an accumulation of inference cycles and an increase in the frequency of the quenching and crystallization steps, the phase change memory cell may lose the median value of the conductance distribution. It is therefore important to verify, after the conductance value modification, that it is within the distribution range defined around the median value of the conductance distribution. The reading step may be performed at a frequency lower than the frequency of the inference cycle.

According to one embodiment, the reading step is performed only on the at least one phase change memory cell that has undergone the quenching and crystallization steps.

In some embodiments, a step of reprogramming the at least one phase change memory cell is performed based on the resistance or conductance value measured during the reading step.

For example, the reprogramming step is performed if the measured conductance value is no longer within the defined distribution range.

The reprogramming step consists of reprogramming the device of interest to the median value of the conductance or resistance distribution, according to a method known to those skilled in the art.

In some embodiments, the phase change material is a chalcogenide material.

The chalcogenide materials are compounds containing at least one metal ion and at least one ion of a chalcogen element, which in particular comprises oxygen, sulfur, selenium, and tellurium.

In some embodiments, the chalcogenide material is incongruent in nature.

An incongruent material forms a liquid at a melting point that has a different chemical composition than the material in solid form.

An integration of an incongruent chalcogenide material allows increasing the variability of the phase change memory cell and thus allows broadening the distribution range that can be obtained during the modification method.

In some embodiments, the chalcogenide material comprises antimony.

An antimony-rich chalcogenide material allows also to improve the distribution range that can be obtained during the modification method.

In some embodiments, the modification current depends on the value of the median conductance, or resistance distribution and the desired resistance distribution range.

In some embodiments, the memory array is a neuromorphic circuit having a 1T1R or 1S1R configuration.

The “1T1R” configuration in a neuromorphic circuit refers to a specific architecture, where “1T” stands for a transistor and “1R” stands for the phase change memory cell. More specifically, the transistor can be a FEOL access transistor, an acronym for «Front-end-of-line». The transistor acts as a switch to control and limit current flow through the phase change memory cell. To change the conductance value of the phase change memory cell, and thus to write a new value, the transistor is turned on, allowing an electrical pulse to flow through the phase change memory cell. Specifically, the greater the current flow, the greater the volume of phase change material that will be melted during the pulse. This allows increasing the range of conductance distribution that can be encoded in the memory cell. However, this leads to a greater risk of losing the median value of the conductance distribution and therefore a need for more frequent reprogramming.

The «1S1R» configuration in a neuromorphic circuit refers to a specific architecture, where «1S» stands for a selector and «1R» stands for the phase change memory cell. The selector can be a BEOL selector device, an acronym for «Back-end-of-line». The selector acts as a switch that allows controlling a current flow through the phase change memory cell in response to a switching voltage. When a new value is to be written to the phase change memory cell, a switching voltage is applied to the 1S1R device. This allows current to flow through the phase change memory cell. The electrical pulses according to the method are then applied, changing the conductance value of the phase change memory cell. After writing, the selector becomes insulating again, protecting the phase change memory cell from leakage currents and interference during read operations in the memory array. An advantage of the “1S1R” configuration is the ability to significantly increase the overall density of the memory array. The 1S1R devices are integrated in a crossbar structure, where it is possible to reduce the memory cell size down to 4F², where F is the smallest size achievable in lithography at a given technology node. This improves the performance of the neuromorphic circuit.

In some embodiments, the neural network is a Bayesian neural network.

A Bayesian neural network is an artificial neural network architecture that incorporates principles of probability and uncertainty during a learning mechanism.

Unlike conventional neural networks, where synaptic weights are fixed values, Bayesian neural networks treat synaptic weights as probability distributions. This makes it possible to model the uncertainty inherent in data and predictions and provide confidence estimates for model predictions. These features make Bayesian neural networks particularly useful in fields where uncertainty assessment is important, such as medicine or finance.

The invention, which allows the conductance value of the phase change memory cell to be modified within a defined distribution range around a median value of the conductance distribution, is particularly suited to Bayesian neural networks.

One embodiment relates to a neural network implementing, during an inference cycle, the method for modifying a conductance or resistance value of at least one phase change memory cell according to the invention.

An inference cycle of the neural network is performed so as to obtain a prediction. The inference cycle corresponds to a use of the neural network. At each inference cycle, the modification method, comprising the quenching step, the crystallization step, and optionally the reading and reprogramming step, is performed.

### BRIEF DESCRIPTION OF THE DRAWINGS

The invention will be better understood from the following description, which relates to an embodiment according to the present invention, given as a non-limiting example and explained with reference to the attached schematic drawings, in which:

FIG. 1 illustrates a change in a resistance value of a phase change memory cell as a function of an applied voltage for eight different initial resistive states.

FIG. 2 is a graph showing the evolution of the threshold voltage of the phase change memory cell as a function of the resistance initially programmed on the cell.

FIG. 3 is a graph showing the evolution of the resistance value of the phase change memory cell as a function of an applied current for four different initial resistive states.

FIG. 4 is a diagram illustrating four distribution ranges and a variation of a median resistance distribution value during inference cycles.

FIG. 5 is a schematic representation of the method according to the invention.

### DESCRIPTION OF EMBODIMENTS

The invention concerns a neural network implementing, during an inference cycle, a method for modifying 100 a conductance or resistance value R_{act} of at least one phase change memory cell C1, C2, C3, C4 comprised in a memory array MM. The neural network comprises a plurality of phase change memory cells C1, C2, C3, and C4 grouped in a memory array MM.

Optionally, the method 100 also comprises a reading step IL during which the conductance or resistance value R_{act} is measured.

An inference cycle of the neural network is performed to obtain a prediction. The inference cycle corresponds to a use of the neural network.

Preferably, the neural network is a Bayesian neural network.

A Bayesian neural network is an artificial neural network architecture that incorporates principles of probability and uncertainty into a learning mechanism.

Unlike conventional neural networks, where synaptic weights are fixed values, Bayesian neural networks treat synaptic weights as probability distributions. This makes it possible to model uncertainty inherent in the data and predictions and to provide confidence estimates for model predictions. These features make Bayesian neural networks particularly useful in fields where uncertainty assessment is important, such as medicine or finance.

The modification method 100, allowing to modify the conductance or resistance value R_{act} of the phase change memory cell C1, C2, C3, C4 within a defined resistance distribution range P_{prog1}, P_{prog2}, P_{prog3}, P_{prog4} around a median value of the conductance distribution, or similarly resistance R_{prog1}, R_{prog2}, R_{prog3}, R_{prog4}, is particularly suited to the Bayesian neural network.

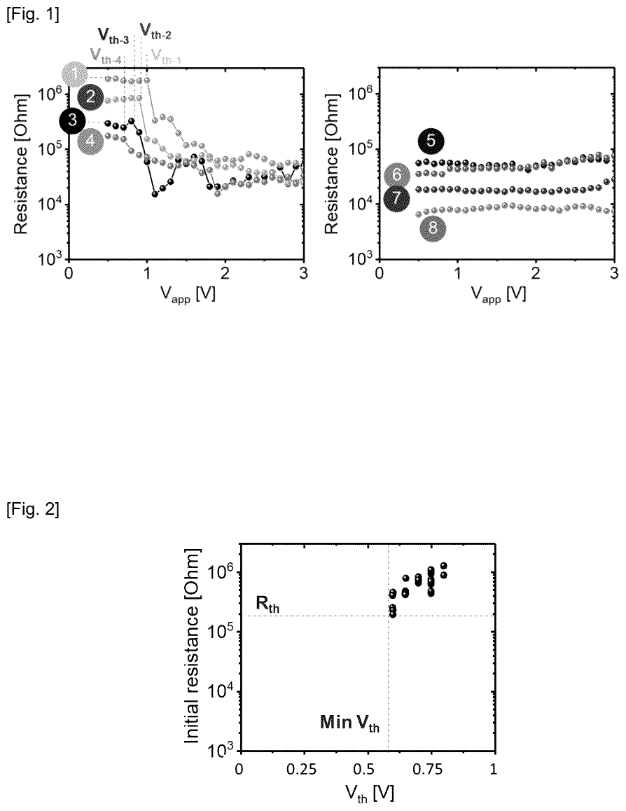

In the remainder of the description, reference is made analogously to the conductance or resistance of the phase change memory cell C1, C2, C3, C4. Indeed, it is known that the resistance and conductance are two intrinsically linked but inverse electrical properties, describing respectively the capacity of a material to oppose or facilitate the passage of electric current. The resistance, measured in ohms, is defined by Ohm's law as the ratio between the voltage and the current through a material. However, the conductance, expressed in siemens, is the inverse of the resistance. Thus, resistance and conductance are inversely proportional: a material with high resistance will have low conductance, and vice versa. In particular, FIGS. 1 to 4 relate to resistance values.

The phase change memory cell C1, C2, C3, C4, called PCM (acronym for «phase change memory») is a type of non-volatile memory that relies on a reversible phase change of a phase change material to store information. More specifically, an electrical resistivity of the phase change material, or in other words the value of its conductance, varies according to a ratio of a highly resistive amorphous phase and a ratio of a low-resistive crystalline phase of said phase change material. The phase change material is comprised between a lower electrode and an upper electrode. The phase change material can assume:
a crystalline state in which the phase change material in contact with the lower electrode is entirely in the crystalline phase,
a partially amorphous state in which the phase change material in contact with the lower electrode is partially in the crystalline phase and partially in the amorphous phase,
a completely amorphous state in which the phase change material in contact with the lower electrode is entirely in the amorphous phase.

In some embodiments, the phase change material is a chalcogenide material. The chalcogenide materials are compounds containing at least one metal ion and at least one ion of a chalcogen element, which comprises in particular oxygen, sulfur, selenium, and tellurium.

In some embodiments, the chalcogenide material is incongruent in nature. An incongruent material forms a liquid at a melting point that has a different chemical composition than the material in solid form. An integration of an incongruent chalcogenide material allows increasing a variability of the phase change memory cell C1, C2, C3, C4 and thus allows broadening the resistance distribution range P_{prog1}, P_{prog2}, P_{prog3}, P_{prog4} that can be obtained during the modification method 100.

In some embodiments, the chalcogenide material comprises antimony. An antimony-rich chalcogenide material also allows improving the resistance distribution range P_{prog1}, P_{prog2}, P_{prog3}, P_{prog4} that can be obtained during the modification method 100.

To determine the state of the phase change material at the interface with the lower electrode of a given phase change memory cell C1, C2, C3, C4, the change in the resistance of the phase change memory cell C1, C2, C3, C4 as a function of different applied voltages Vₐₚₚ is measured. A detection of a threshold voltage Vₜₕ₋₁, Vₜₕ₋₂, Vₜₕ₋₃, Vₜₕ₋₄, that is to say, a voltage at which a sudden decrease in the resistance value of the phase change memory cell C1, C2, C3, C4 is detected, indicates a completely amorphous state of the material at the interface with the lower electrode.

The threshold resistance, respectively conductance, Rₜₕ, respectively 1/Rₜₕ, refers to the resistance, respectively conductance, of the phase change memory cell at which a threshold voltage is detected.

In the method according to the invention, the plurality of phase change memory cells C1, C2, C3, C4 of the memory array MM are initially programmed so as to have a crystalline or partially amorphous state at an interface with a lower electrode.

FIG. 1 illustrates an evolution of the resistance value of a phase change memory cell as a function of an applied voltage Vₐₚₚ for eight different starting resistive states 1, 2, 3, 4, 5, 6, 7, 8. In the left graph, a threshold voltage Vₜₕ₋₁, Vₜₕ₋₂, Vₜₕ₋₃, Vₜₕ₋₄ is detected for the four resistive states 1, 2, 3, 4 illustrated on the left. This indicates that an amorphous phase completely covers the interface with the lower electrode of the memory cell. These are therefore four completely amorphous resistive states 1, 2, 3, 4. A breakdown of the amorphous phase completely covering the interface with the lower electrode of the memory cell takes place at the threshold voltage Vₜₕ₋₁, Vₜₕ₋₂, Vₜₕ₋₃, Vₜₕ₋₄. This results in a steep drop in resistance of the phase change memory cell. In the right graph, no threshold voltage Vₜₕ is detected for the four resistive states 5, 6, 7, 8 shown on the right. This indicates that the amorphous phase does not completely cover the interface with the bottom electrode of the memory cell. Therefore, there are four resistive states 5, 6, 7, 8 which are either crystalline or partially amorphous.

The phase change is achieved by applying an electrical pulse I1, I2, between the lower and upper electrodes, which heats the phase change material of the phase change memory cell C1, C2, C3, C4 by the Joule effect.

The electrical pulse I1, I2 is defined as having a rising ramp during which the pulse current increases and goes from a minimum value, which may be equal to zero, to a maximum value, corresponding to the nominal current value, subsequently also referred to as the modification current Iapp, and a falling ramp during which the pulse current decreases and goes from the nominal current value to the minimum value.

Depending on the applied falling ramp, the phase change material changes state so as to become more crystalline or more amorphous than before the pulse was applied.

More specifically, rapid cooling of the phase change material, that is to say, a steep falling ramp, results in the presence of the amorphous phase, while slow cooling, that is to say, a gradual ramp, results in the appearance of the crystalline phase at the interface with the lower electrode.

For example, a pulse I1 with a rectangular profile corresponds to a pulse whose rising and falling ramps are substantially instantaneous, so that the current rise and fall are rapid. The pulse I1 with a rectangular profile results in rapid cooling of the phase change material, which induces the appearance of the amorphous phase at the interface with the lower electrode.

The duration of the applied pulses I1, I2 is a standard pulse duration in a neural network, typically in the range of a hundred nanoseconds. The nominal current value of the pulse Iapp is therefore decisive in the temperature and quantity of phase change material heated by the pulse, and therefore the quantity of material at the interface with the lower electrode capable that can undergo a phase change.

In some embodiments, a steep falling ramp can be defined as having a duration less than or equal to 30 ns. In other words, a transition from the modification current Iapp to the minimum current is achieved with a duration less than or equal to 30 ns.

In some embodiments, a gradual falling ramp can be defined as having a duration greater than 30 ns and preferably greater than or equal to 60 ns. In other words, a transition from the modification current Iapp to the minimum current is achieved with a duration greater than 30 ns and preferably greater than or equal to 60 ns.

A phase change in the material of the phase change memory cell C1, C2, C3, C4 causes a variation in the conductance or resistance of the latter. Thus, the more the material of the phase change memory cell C1, C2, C3, and C4 is in a crystallized state, the lower its resistance, while the more the material of the phase change memory cell C1, C2, C3, and C4 is in an amorphous state, the higher its resistance.

The value of the modification current Iapp is also very important in determining the phase change that will occur when the electrical pulse is applied.

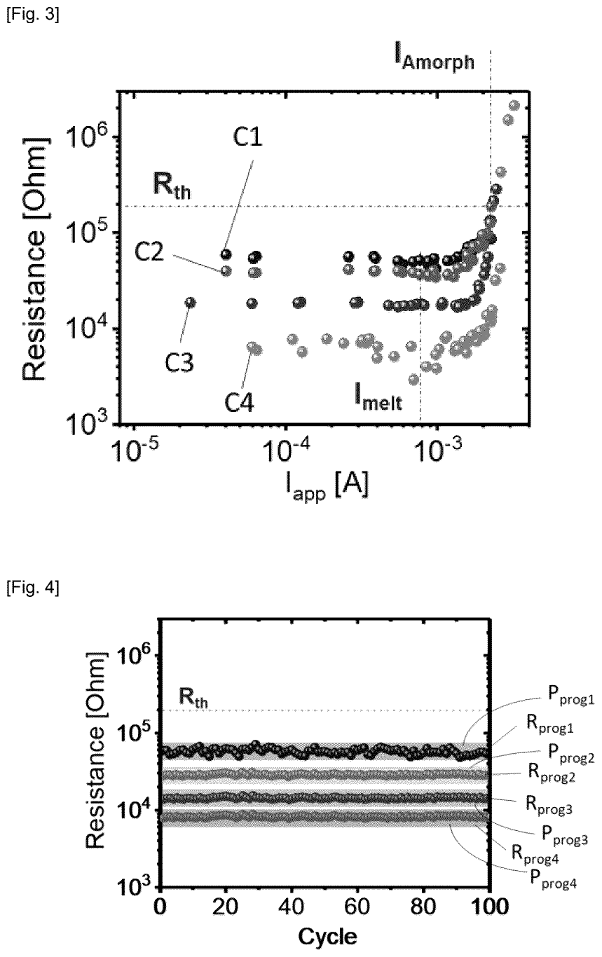

FIG. 3 illustrates the evolution of the resistance value R_{prog1}, R_{prog2}, R_{prog3}, R_{prog4} of a phase change memory cell as a function of an applied current Iapp across its terminals for four different initial resistive states C1, C2, C3, and C4. In C1, the phase change memory cell was initially programmed with a 70 kOhm resistor. In C2, the phase change memory cell was initially programmed with a 40 kOhm resistor. In C3, the phase change memory cell was initially programmed with a 20 kOhm resistor. In C4, the phase change memory cell was initially programmed with an 8 kOhm resistor. All states are programmed to ensure a crystalline or partially amorphous state, meaning that the interface with the lower electrode is not completely covered with amorphous phase.

FIG. 2 shows a graph showing the evolution of the threshold voltage Vₜₕ of the phase change memory cell in FIG. 1 as a function of the initial resistive state 1, 2, 3, 4, 5, 6, 7, 8 of the initially programmed resistor on the cell. The minimum resistance at which a threshold voltage Vₜₕ is detected in the phase change memory cell of the memory array corresponds to a threshold resistance Rₜₕ. The associated threshold conductance is equal to 1/Rₜₕ.

Using this type of graph, it is possible to determine a melting current Imelt, an amorphous phase current Iamorph, a threshold resistance Rₜₕ, and a threshold voltage Vₜₕ of the phase change memory cell.

These graphs allow in particular to determine:
the melting current Imelt, which corresponds to a nominal current value of a pulse for which at least a quantity of the phase change material in contact with the lower electrode can change phase such that the conductance value of the phase change memory cell C1, C2, C3, C4 varies. A pulse applied to the phase change memory cell C1, C2, C3, C4 with a nominal current lower than the melting current Imelt causes no phase change and therefore no change in conductance 1/R_{act} or resistance R_{act};
the amorphous phase current Iamorph, which corresponds to the nominal current value of a pulse beyond which the phase change material becomes completely amorphous at the interface with the lower electrode;
the threshold resistance Rₜₕ, for which the phase change material is completely amorphous at the interface with the lower electrode;
The minimum threshold voltage Vₜₕ, corresponding to the voltage required to induce breakdown of the amorphous phase completely covering the interface with the lower electrode of a programmed memory cell with a resistance equal to the threshold resistance Rₜₕ.

The amorphous phase current is determined by successively applying a pulse with a steep falling ramp having a quenching effect to the phase change memory cell, starting with a crystalline state. These pulses will gradually modify the conductance value, or resistance, of the phase change memory cell. When a threshold voltage appears in the phase change memory cell, that is to say when the phase change memory cell is in a completely amorphous state at the interface with the lower electrode, the current of the last applied pulse is defined as the amorphous phase current.

In other words, from the pulse current value leading to the appearance of a threshold voltage, and therefore the creation of a completely amorphous state at the interface with the lower electrode, the threshold resistance and the amorphous phase current corresponding to said pulse current value are deduced.

During a learning phase 200, the phase change memory cell C1, C2, C3, C4 is programmed so that the conductance value 1/R_{act} or resistance R_{act} is equal to a median conductance distribution value 1/R_{prog1}, 1/R_{prog2}, 1/R_{prog3}, 1/R_{prog4} or resistance R_{prog1}, R_{prog2}, R_{prog3}, R_{prog4}. The median resistance distribution values R_{prog1}, R_{prog2}, R_{prog3}, R_{prog4} are always programmed so as to always be lower than the threshold resistance Rₜₕ. The median conductance distribution values 1/R_{prog1}, 1/R_{prog2}, 1/R_{prog3}, 1/R_{prog4} are always programmed so as to always be greater than the threshold conductance 1/Rₜₕ. There are several ways of programming the phase change memory cell C1, C2, C3, C4 known to those skilled in the art.

Then, during an inference phase, the method 100 seeks to modify the conductance or resistance value R_{act} of the phase change memory cell C1, C2, C3, C4 in the resistance distribution range P_{prog1}, P_{prog2}, P_{prog3}, P_{prog4} defined around this median value of the conductance distribution 1/R_{prog1}, 1/R_{prog2}, 1/R_{prog3}, 1/R_{prog4}, respectively resistance R_{prog1}, R_{prog2}, R_{prog3}, R_{prog4}, so as to always remain higher, respectively lower, than the threshold conductance 1/Rₜₕ, respectively threshold resistance Rₜₕ. The resistance distribution range P_{prog1}, P_{prog2}, P_{prog3}, P_{prog4} is defined between a lower resistance value and an upper resistance value, determined during the learning phase 200. The resistance distribution R_{prog1}, R_{prog2}, R_{prog3}, R_{prog4} of the phase change memory cell must always remain lower than the threshold resistance Rₜₕ.

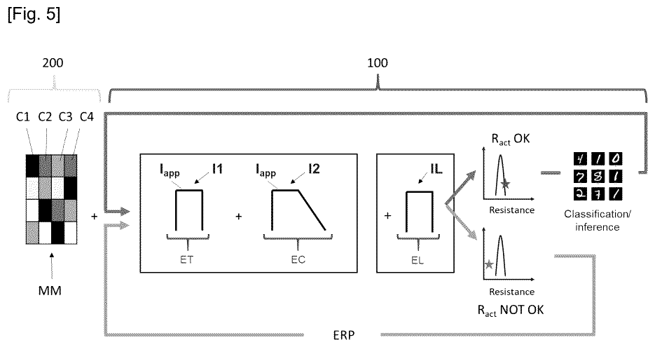

The objective of the modification method 100 is illustrated in FIG. 5. It involves, at each inference cycle, modifying the conductance or resistance value of the cell while maintaining the conductance value 1/R_{act} or resistance R_{act}, R_{act} corresponding to the resistance value R_{prog1}, R_{prog2}, R_{prog3}, R_{prog4} in FIG. 4, within the distribution range, corresponding to the resistance distribution ranges P_{prog1}, P_{prog2}, P_{prog3}, P_{prog4}. These resistance distribution ranges P_{prog1}, P_{prog2}, P_{prog3}, P_{prog4} are defined around the median resistance distribution value R_{prog1}, R_{prog2}, R_{prog3}, R_{prog4}. FIG. 4 illustrates a variation of the median resistance distribution value R_{prog1}, R_{prog2}, R_{prog3}, R_{prog4} during inference cycles by implementing the modification method 100. We see that this median resistance distribution value R_{prog1}, R_{prog2}, R_{prog3}, R_{prog4} is substantially constant. The median resistance distribution value R_{prog1}, R_{prog2}, R_{prog3}, R_{prog4} being an image of the resistance value, the modification method 100 makes it possible to maintain the median resistance distribution value over time.

The modification method 100 is more particularly illustrated in FIG. 5. As already explained, the method 100 aims to modify the conductance value 1/R_{act} or resistance R_{act} of the phase change memory cell C1, C2, C3, C4, during the inference cycles, so that the conductance value 1/R_{act} or resistance R_{act} remains within the resistance distribution range P_{prog1}, P_{prog2}, P_{prog3}, P_{prog4} defined around the median value of the resistance distribution R_{prog1}, R_{prog2}, R_{prog3}, R_{prog4}.

To this end, the method 100 comprises a determination step. During this step, the melting current Imelt, the amorphous phase current Iamorph, and optionally the minimum threshold voltage Vₜₕ and the threshold resistance Rₜₕ are determined for the phase change memory cell C1, C2, C3, C4.

Then, the method 100 comprises a quenching step ET. In this step, a first electrical pulse I1 is applied to the phase change memory cell C1, C2, C3, C4. The first pulse I1 has a steep falling ramp leading to the appearance of an amorphous phase in the phase change material, for example a rectangular pulse profile, and a modification current Iapp greater than or equal to the melting current Imelt and strictly less than the amorphous phase current Iamorph. Thus, the modification current Iapp is selected to be sufficient to locally melt the phase change material while allowing for an electrical consumption lower than an electrical consumption associated with a programming pulse. Furthermore, the use of such a modification current Iapp, lower than the amorphous phase current Iamorph, degrades the phase change memory cell C1, C2, C3, C4 to a lesser extent and therefore allows a longer lifespan. After the quenching step ET, the resistance value R_{act} of the phase change memory cell C1, C2, C3, and C4 is therefore increased.

The method also comprises a crystallization step EC. In this step, a second electrical pulse I2 is applied to the phase change memory cell C1, C2, C3, and C4. The second pulse I2 has a progressive falling ramp allowing the appearance of a crystalline phase in the phase change material, at the modification current Iapp. The falling ramp of the second pulse I2 allows the local creation of a crystalline phase in the phase change material. After the crystallization step, the resistance value R_{act} of the phase change memory cell C1, C2, C3, and C4 is therefore reduced.

The method 100 does not define an order of execution between the quenching step ET and the crystallization step EC. The quenching step ET can therefore be followed by the crystallization step EC or carried out after the latter.

Furthermore, the modification current Iapp applied during the first pulse I1 is equal to the modification current Iapp applied during the second pulse I2.

Thus, the increase in resistance achieved during the quenching step ET is substantially equal to the reduction in resistance achieved during the crystallization step EC, so that the value of the resistance R_{act} remains within the resistance distribution range P_{prog1}, P_{prog2}, P_{prog3}, P_{prog4} defined around the median value of the resistance distribution R_{prog1}, R_{prog2}, R_{prog3}, R_{prog4}.

Carrying out the two steps ET, EC of the method 100 makes it possible to maximize maintenance of the resistance value R_{act} of the phase change memory cell C1, C2, C3, C4 in the resistance distribution range P_{prog1}, P_{prog2}, P_{prog3}, P_{prog4} defined around the median value of the resistance distribution R_{prog1}, R_{prog2}, R_{prog3}, R_{prog4}. Thus, the median value of the resistance distribution R_{prog1}, R_{prog2}, R_{prog3}, R_{prog4} is stable during the inference cycles while guaranteeing satisfactory cycle-to-cycle variability of the resistance value R_{act} of the phase change memory cell C1, C2, C3, C4.

In some embodiments, during the determination step, an overall maximum melting current and an overall minimum amorphous phase current are determined. The overall maximum melting current corresponds to the maximum of the melting currents determined for each phase change memory cell C1, C2, C3, C4 of the memory array MM. In other words, if a pulse at the overall maximum melting current is applied to all of the phase change memory cells C1, C2, C3, C4 of the memory array MM, then at least a partial localized melting of the phase change material at the interface with the lower electrode will take place on all of the phase change memory cells C1, C2, C3, C4 of the memory array MM. Thus, the resistance values R_{act} of all of the phase change memory cells C1, C2, C3, C4 of the memory array MM will be modulated.

The overall minimum amorphous phase current corresponds to the minimum of the amorphous phase currents determined for each phase change memory cell C1, C2, C3, and C4 of the memory array MM. In other words, if a pulse with the overall minimum amorphous phase current is applied to all the phase change memory cells C1, C2, C3, and C4 of the memory array MM, then at least one phase change memory cell C1, C2, C3, and C4 of the memory array MM will transition to the fully amorphous state.

To determine the overall minimum amorphous phase current, the conductance, or resistance, of all the phase change memory cells C1, C2, C3, and C4 of the memory array MM is modified to increasing resistance values, starting with a crystalline state. To do this, pulses with a steep falling ramp, a quenching effect, and an increasing modification current are applied to all the memory cells. For each resistive state, the occurrence of a minimum threshold voltage MIN Vₜₕ across all phase change memory cells in the memory array is evaluated. As long as no minimum threshold voltage MIN Vₜₕ is detected, pulse injection with a steep falling ramp having a quenching effect at a higher modification current continues. The modification current for which a minimum threshold voltage MIN Vₜₕ is detected across one or more cells C1, C2, C3, C4 of the memory array MM is defined as the «overall minimum amorphous phase current».

In some embodiments, during the quenching step ET, the first pulse I1 with the modification current Iapp is applied simultaneously to all of the phase change memory cells C1, C2, C3, C4 of the memory array MM, and during the crystallization step EC, the second pulse I2 is applied simultaneously to all of the phase change memory cells C1, C2, C3, C4 of the memory array MM. All of the phase change memory cells C1, C2, C3, C4 of the memory array MM are therefore subjected to the same pulse. Thus, the resistance value R_{act} of all of the phase change memory cells C1, C2, C3, C4 is modified at the same time.

In some embodiments, the modification current Iapp is greater than or equal to the overall maximum melting current and strictly less than the overall minimum amorphous phase current. Thus, the modification current Iapp is identical for all phase change memory cells C1, C2, C3, C4. It is therefore not necessary to know, and therefore to store in memory, the melting currents Imelt, amorphous phase current Iamorph and modification current Iapp for each phase change memory cell C1, C2, C3, C4.

In some embodiments, the falling ramp of the first pulse I1 is twice as fast as the falling ramp of the second pulse I2.

In some embodiments, the modification current Iapp is comprised between the melting current Imelt and 1.2 times the melting current Imelt. From experience, 1.2 times the melting current Imelt is always less than the amorphous phase current Iamorph. Thus, the resistance value R_{act} of the at least one phase change memory cell C1, C2, C3, C4 is around the median value.

In some embodiments, the modification current Iapp depends on the value of the median of the conductance distribution 1/R_{prog1}, 1/R_{prog2}, 1/R_{prog3}, 1/R_{prog4}, or of the resistance distribution R_{prog1}, R_{prog2}, R_{prog3}, R_{prog4}, and the desired resistance distribution range P_{prog1}, P_{prog2}, P_{prog3}, P_{prog4}.

In some embodiments, the method 100 comprises a reading step EL in which a reading pulse IL at a reading voltage is applied to the at least one phase change memory cell C1, C2, C3, C4 in order to measure the value of the resistance R_{act}. The reading voltage is not high enough to modify the resistance R_{act} of the phase change memory cell C1, C2, C3, C4, that is to say, the reading voltage cannot change the phase of the phase change material. The reading voltage is therefore lower than the threshold voltage Vₜₕ. Preferably, the reading voltage is lower than the minimum threshold voltage MIN Vₜₕ of the memory array MM. The reading step EL makes it possible to measure and determine the resistance value R_{act} of the phase change memory cell C1, C2, C3, C4. More particularly, the reading step EL can precisely measure the exact resistance value R_{act} or determine only whether the resistance value R_{act} is within the resistance distribution range P_{prog1}, P_{prog2}, P_{prog3}, P_{prog4} defined around the median conductance or resistance distribution value R_{prog1}, R_{prog2}, R_{prog3}, R_{prog4}.

The reading step EL is part of the modification method 100 in that it corresponds to controlling the obtained resistance value R_{act}.

The reading step EL is performed after the quenching step ET and the crystallization step EC have been completed.

With an accumulation of inference cycles and an increase in the frequency of performing the quenching ET and crystallization EC steps, the phase change memory cell C1, C2, C3, C4 may lose the median value of the conductance distribution 1/R_{prog1}, 1/R_{prog2}, 1/R_{prog3}, 1/R_{prog4}, or resistance R_{prog1}, R_{prog2}, R_{prog3}, R_{prog4}. It is therefore important to check after performing the modification of the resistance value R_{act} that it is within the range of the resistance distribution P_{prog1}, P_{prog2}, P_{prog3}, P_{prog4} defined around the median value of the resistance distribution R_{prog1}, R_{prog2}, R_{prog3}, R_{prog4}. The reading step EL can be performed at a frequency lower than a frequency of the inference cycle.

According to one embodiment, the reading step EL is performed only on the at least one phase change memory cell C1, C2, C3, C4 that has undergone the quenching ET and crystallization EC steps.

Then, based on the resistance value R_{act} measured during the reading step EL, a reprogramming step ERP is performed. The reprogramming step ERP consists of reprogramming the median value of the conductance, or resistance distribution R_{prog1}, R_{prog2}, R_{prog3}, R_{prog4} according to a method known to those skilled in the art, if the measured resistance value R_{act} is no longer within the defined resistance distribution range P_{prog1}, P_{prog2}, P_{prog3}, P_{prog4}.

The reprogramming step ERP is similar to the programming steps occurring during the learning phase 200.

In some embodiments, the phase change memory cell C1, C2, C3, and C4 is integrated into a neuromorphic circuit having a 1T1R or 1S1R configuration.

The “1T1R” configuration in a neuromorphic circuit refers to a specific architecture, where “1T” signifies a transistor and “1R” corresponds to the phase change memory cell C1, C2, C3, and C4. More specifically, the transistor may be a FEOL access transistor, an acronym for «Front-end-of-line». The transistor acts as a switch to control and limit current flow through the phase change memory cell C1, C2, C3, and C4. To change the resistance value R_{act} of the phase change memory cell C1, C2, C3, C4, and thus to write a new value, the transistor is activated, allowing an electrical pulse to flow through the phase change memory cell C1, C2, C3, C4. More specifically, the greater the current flow, the greater the volume of phase change material that will be melted during the pulse. This increases the range of conductance distribution that can be encoded in the memory cell. However, this carries a greater risk of losing the median value of the conductance distribution, or resistance R_{prog1}, R_{prog2}, R_{prog3}, R_{prog4}, and therefore a need for more frequent reprogramming.

The “1S1R” configuration in a neuromorphic circuit refers to a specific architecture, where “1S” stands for a selector and “1R” stands for the phase change memory cell C1, C2, C3, C4. The selector can be a BEOL selector device, an acronym for «Back-end-of-line». The selector acts as a switch that controls current flow through the phase change memory cell C1, C2, C3, C4 in response to a switching voltage. When a new value is to be written to the phase change memory cell C1, C2, C3, C4, a switching voltage is applied to the 1S1R device. This allows current to flow through the phase change memory cell C1, C2, C3, C4. The electrical pulses according to the method are then applied, changing the conductance value of the phase change memory cell C1, C2, C3, C4. After writing, the selector becomes insulating again, thus protecting the phase change memory cell from leakage currents and interference during read operations in the memory array MM. An advantage of the “1S1R” configuration is the ability to significantly increase the overall density of the memory array MM. The devices 1S1R are integrated in a Crossbar structure, where it is possible to reduce the memory cell size down to 4F², where F is the smallest size that can be achieved in lithography in a given technology node. This improves the performance of the neuromorphic circuit.

Although the present invention has been described with reference to specific embodiments, it is evident that modifications and changes may be made to these examples without departing from the general scope of the invention as defined by the claims. In particular, individual features of the various illustrated/mentioned embodiments may be combined in additional embodiments. Therefore, the description and drawings should be considered in an illustrative rather than restrictive sense.

It is also evident that all features described with reference to a method are transposable, alone or in combination, to a device, and conversely, all features described with reference to a device are transposable, alone or in combination, to a method.

1. A method for modifying a conductance value, or resistance, respectively, in a resistance distribution range defined around a median resistance distribution value, or conductance, respectively, of at least one phase change memory cell, the at least one phase change memory cell being comprised in a memory array comprising a plurality of memory cells, the at least one memory cell comprising a lower electrode, an upper electrode, and a phase change material located between the lower electrode and the upper electrode, the phase change material being capable of assuming a crystalline, partially amorphous or completely amorphous state at an interface with the lower electrode, the method being implemented by a neural network and comprising:
a determination step in which a melting current and an amorphous phase current are determined for the at least one phase change memory cell, the melting current corresponding to the current causing at least a partial localized melting of the phase change material at the interface with the lower electrode when it is applied to the at least one phase change memory cell, the amorphous phase current corresponding to the current causing a creation of a completely amorphous state at the interface with the lower electrode when it is applied to the at least one phase change memory cell;
a quenching step in which a first pulse at a modification current greater than or equal to the melting current and strictly less than the amorphous phase current is applied to the at least one phase change memory cell, the first pulse having a rising ramp then a steep falling ramp having a quenching effect;
a crystallization step in which a second pulse at the modification current is applied to the at least one phase change memory cell, the at least one phase change memory cell being identical to the at least one phase change memory cell of the quenching step, the second pulse having a rising ramp then a gradual falling ramp.

2. The method according to claim 1, wherein the median conductance distribution value, or respectively resistance distribution value, as well as the conductance distribution range, or respectively resistance distribution range, of the at least one phase change memory cell are defined as being greater than, respectively less than, a threshold conductance 1/Rₜₕ, respectively threshold resistance, corresponding to a conductance, or respectively resistance, of the at least one phase change memory cell for which a threshold voltage is detected.

3. The method according to claim 1, wherein the steep falling ramp of the first pulse has a duration less than or equal to 30 ns.

4. The method according to claim 1, wherein the progressive falling ramp of the second pulse has a duration greater than 30 ns.

5. The method according to claim 1, wherein the modification current is comprised between the melting current and 1.2 times the melting current.

6. The method according to claim 1, further comprising a reading step in which a reading pulse at a reading voltage is applied to the at least one phase change memory cell in order to measure the value of the resistance or conductance.

7. The method according to claim 6, wherein a reprogramming step of the at least one phase change memory cell is carried out as a function of the resistance or conductance value measured during the reading step.

8. The method according to claim 1, wherein the phase change material is a chalcogenide material.

9. The method according to claim 1, wherein the modification current depends on the value of the median of the conductance distribution, or resistance, and the desired resistance distribution range.

10. The method according to claim 1, wherein the memory array is a neuromorphic circuit having a 1T1R or 1S1R configuration.

11. The method according to claim 1, wherein the neural network is a Bayesian neural network.

12. A neural network implementing, during an inference cycle, the method for modifying a conductance or resistance value, of at least one phase change memory cell according to claim 1.
